(19) United States
(12) Patent Application Publication
(10) Pub. No.: US 2005/0011027 A1
(43) Pub. Date: Jan. 20, 2005

(54) Contact actuator with contact force control

(75) Inventors: Laurent Heiniger, Fontainemelon (CH); Claude Froidevaux, La Chaux-de-Fonds (CH); Joel Perret, La Chaux-de-Fonds (CH); Pascal Hostettler, La Chaux-de-Fonds (CH)

Correspondence Address: PEARNE & GORDON LLP, 1801 EAST 9TH STREET, SUITE 1200, CLEVELAND, OH, 44114-3108, US

(73) Assignee: Ismeca Semiconductor Holding SA, La Chaux-de-Fonds (CH)

(21) Appl. No.: 10/919,107

(22) Filed: Aug. 16, 2004

Related U.S. Application Data
(63) Continuation of application No. PCT/CH03/00043, filed on Jan. 21, 2003.

(30) Foreign Application Priority Data
Feb. 20, 2002 (CH) 2002CH-0288

(51) Int. Cl. G01R 1/067

(52) U.S. Cl. 15/22.1; 700/213

(57) ABSTRACT

System for actuating a contactor of electronic component for the electric testing of said components, whose movement is generated by an electromechanical transducer and controlled by a control system limiting the pressing force of the contactor on the component to be tested.

### REFERENCE DATA

This application is a continuation of PCT application 2003WO-CH00043 (WO03071288) filed on Jan. 21, 2003, under priority of Swiss patent application 2002CH-0288 filed on Feb. 20, 2002, the contents whereof are hereby incorporated.

### FIELD OF THE INVENTION

The present invention concerns a system for actuating a contactor for the automatic testing of electronic components.

### DESCRIPTION OF THE RELATED ART

Production lines of semi-conductor components or assembly lines of electronic circuits generally comprise a processing line on which the electronic components undergo a series of operations, including at least one electric testing stage. This electric testing stage allows to check the functioning of each component and to eliminate any faulty component before it is processed in view of its transfer onto another production line or before it is integrated into an electronic circuit, for example.

For productivity reasons, these production or assembly lines are entirely automated and their processing rate must be maximal. The stopping time during which the components are immobilized at each processing station will depend on the time required for the longest operation. Thus, each operation must be performed in a minimum of time. The operations including an electric test are often among the longest, since they require an electric contact to be established between the component to be tested and the testing apparatus, the performance of the test, then the interruption of the electric contact. As it is difficult to compress the testing time itself, it is important that the time necessary for establishing and interrupting the electric contact should be minimal.

In the case of components having radial exits, the electric contact between the component to be tested and the testing apparatus is generally established by means of a contactor comprising a series of elastic metallic blades that are either pressed on the component to be tested at certain precise points of contact, or arrayed in pairs for squeezing, in the manner of pliers or pincers, one or several contact points of the component, such as for example one of its leads. The two contact modes can also be combined on the same contactor. For grid array components, for example of the type “pin grid array” (PGA) or “ball grid array” (BGA), the contactor most often comprises a plate of metallic contacts arranged opposite the components' contacts and applied against its lower surface. The contactors are made fully automatic and integrated in the processing line. They are generally moved by their own movement generator, synchronized with the rate of the components' processing line.

Patents U.S. Pat. No. 5,850,146, U.S. Pat. No. 4,956,923 and U.S. Pat. No. 6,344,751 illustrate by way of example various forms of component contactors of the prior art.

Most of the current systems use pneumatic jacks as movement generator. However, the acceleration of these systems is limited by their inertia, due to the mass of the pieces in movement and to the use of a pneumatic energy source. Their speed is thus very limited, in particular over short distances. Also due to the masses in movement, such systems are subjected to rapid aging of their mechanism, which thus affects their life expectancy.

Furthermore, the contactor must perform precise and reproducible movements. In particular, the speed of the flexible blades during establishment of the contact with the component as well as the contact force must be perfectly controlled, in order to avoid damaging the component whilst ensuring a good quality of the electric contact. Yet generating precise movements with a pneumatic jack requires components that are precise and thus expensive, as well as a complex regulating of the jack's control.

An aim of the invention is to propose a system for actuating a contactor of electronic components that is faster than the prior art systems.

Another aim of the invention is to propose a system for actuating a component contactor having a long life thanks to a mild wearing of its mechanical parts.

Another aim of the invention is to propose a system for actuating a component contactor and whose movements are precise and reproducible.

### BRIEF SUMMARY OF THE INVENTION

These stated aims are achieved by a system having the characteristics of the independent claim; preferred embodiments of the system can comprise the characteristics of the dependent claims. In particular, the actuating system according to the invention has, as movement generator, a linear electromechanical transducer. In a preferred embodiment, in order to compensate the inaccuracies of the transducer's displacements, the speed control and the regulating of the pressing force of the contactor on the component to be tested are performed by means of a control mechanism comprising at least one connecting rod.

### BRIEF DESCRIPTION OF THE DRAWINGS

The present invention will be better understood with the aid of the attached FIGS. 1 to 3 illustrating, by way of explanatory but by no means limiting example, the preferred embodiment of the actuating system according to the invention.

FIG. 1 shows a lateral view of the actuating system according to the preferred embodiment of the invention.

FIGS. 2a and 2b show a top view of the movement generator according to the preferred embodiment of the invention.

FIG. 3 shows the functioning principle of the system for controlling the speed and the squeezing force of the contactor according to the preferred embodiment of the invention.

### DETAILED DESCRIPTION OF THE INVENTION

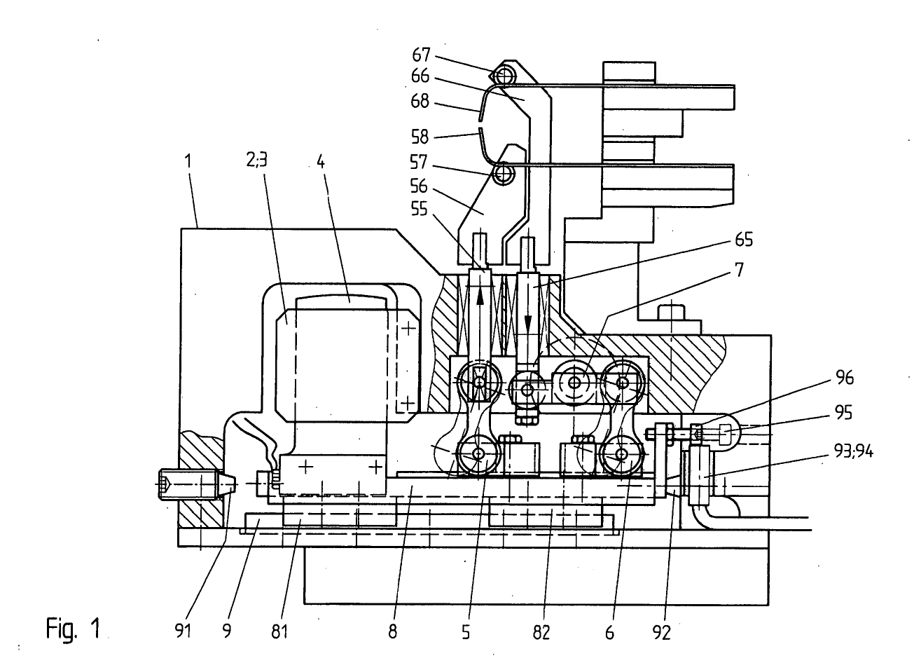

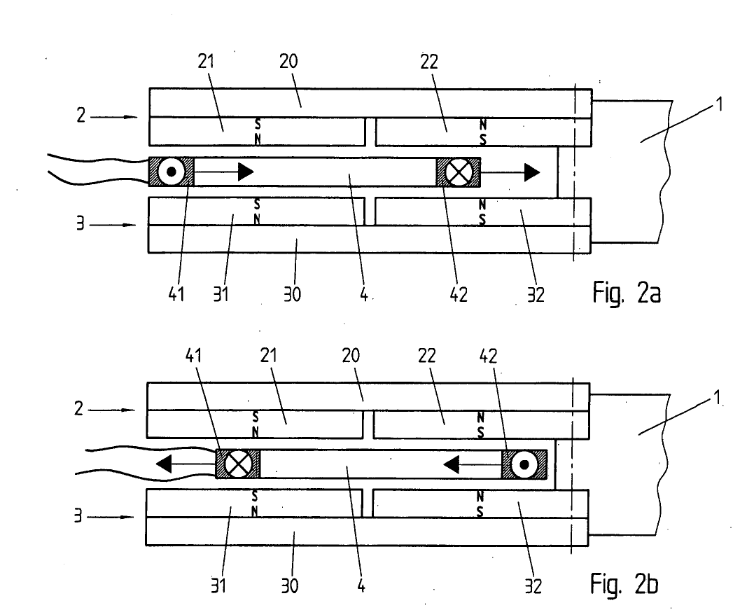

With reference to FIGS. 2a and 2b, the actuating system according to the preferred embodiment of the invention comprises two fixed blocs of permanent magnets 2, 3, preferably connected parallel to one another to the frame 1 of the system. Each block of permanent magnets 2, 3 comprises for example two magnets 21, 22 and 31, 32 held on their support 20, 30 respectively, so as to generate, in the space between the two magnet blocks 2, 3, a magnetic field whose direction at the two extremities is inverted. An electric coil 4 is placed between the two magnet blocs 2, 3, its axis being generally perpendicular to the plane of the two magnet blocs 2, 3. The electric coil 4 is fastened on a carriage 8 (FIG. 1) that is held and guided by runners 81, 82 on rails 9 more or less parallel to the median-perpendicular plane of the shortest segment between said two blocs of permanent magnets 2, 3. Stops 91, 92 are situated on both sides of the carriage in order to restrict the amplitude of its movements and to thus determine two discrete positions of the carriage 8. The carriage 8 comprises two adjustable markers, preferably metal-head screws 95, 96. When the carriage 8 is in its first discrete position, against the first stop 91, the first marker, preferably the head of the first screw 95, is situated above a first position detector, preferably a first induction sensor 93. When the carriage is in its second discrete position, against the second stop 92, the second marker, preferably the head of the second screw 96, is situated above a second position detector, preferably a second induction sensor 94.

The contactor illustrated here by way of example comprises two series of flexible metallic blades 58, 68 arrayed in pairs and squeezing the leads of the components to be tested in the manner of pincers or pliers, of which only the first pair is visible in FIG. 1. The contactor is closed and opened by the opposite vertical movements of two jaws 56, 66. Each jaw drives in its movement one of the two series of flexible blades 58, 68 through a cylinder 57, 67 electrically insulated. Each jaw 56, 66 is fastened at the upper extremity of an axle 55, 65 guided in a vertical cylinder through the frame 1.

A first connecting rod 5 is connected by its lower axle to the carriage 8 and by its upper axle to the lower extremity of the first axle 55. A second connecting rod 6 is fastened by its lower axle to the carriage 8 and by its upper axle to a more or less horizontal reversing lever 7 that can rotate around an axle situated in its middle. The other extremity of the reversing lever 7 is connected around a rotation axis to the lower extremity of the second axle 65.

In its preferred embodiment, the linear electromechanical transducer generating the movement of the inventive actuating system is a voice coil motor. The voice coil motor comprises the two blocks of permanent magnets 2, 3 and the mobile electrical coil 4 placed between them and through which a control system (not represented) comprising an electric generator can send a continuous current of variable intensity and direction. The electric coil 4 is more or less rectangular and its vertical dimension is greater than that of the magnet blocks 2, 3. It is positioned so that the portions of spires 41, 42, placed in the magnetic field between the two magnet blocks 2, 3 are vertical. Thus, when a continuous current runs through the coil 4, the latter′s behavior in the magnetic field between the two magnet blocks 2, 3 can be assimilated to that of two vertical electric conductors through which a current of same intensity but of opposite direction runs and that are placed in a magnetic field of opposite direction. Each conductor is subjected to a force in the same direction, perpendicular to the plane formed by the direction of the electric current and the direction of the magnetic field, whose value is proportional to the current′s intensity and to the magnetic flux.

In the preferred embodiment of the actuating system, the direction of the forces exerted on the vertical portions 41, 42 of the spires of the coil 4 is thus parallel to the rails 9 (FIGS. 2a and 2b). The coil will consequently move in the direction of the force exerted on it, driving the carriage in its movement until the latter is blocked by one of the stops 91, 92.

In the example illustrated in FIG. 2a, the coil 4 thus moves until the carriage 8 reaches its second discrete position against the second stop 92. Inverting the current will generate a force of opposite direction on the coil 4 (FIG. 2b), which causes the carriage 8 to return to its first discrete position, against the first stop 91.

By rapidly alternating the direction of the current circulating in the coil 4, it is possible to generate a quick back-and-forward movement between the two discrete positions of the carriage, thus causing the rapid closing and opening of the contactor.

The induction sensors 93, 94 detecting the presence of the screw 95, 96 notify the control system of the position of the carriage 8 in its first or second discrete position, thus allowing the optimal moment for the beginning of the testing or the return of the carriage to its previous position to be determined.

Preferably, control of the system for actuating the contactor according to the invention during a testing cycle is performed in the manner described hereafter.

A current of strong intensity is injected in the coil in order to bring the carriage 8 against the second stop 92 and thus to close the contactor onto the component to be tested. When the presence of the head of the second screw 96 is detected by the second induction sensor 94, the latter transmits the information to the actuating system that the contactor is closed. The current's intensity and direction are held during approximately 10 milliseconds after this signal in order to press the carriage 8 hard against the stop 92 to dampen the vibrations of the carriage 8. After this interval, a current of less intensity and of same direction than the preceding one is injected through the coil, generating a force sufficient for holding the carriage 8 against the second stop 92 during the entire duration of the test.

Once the test is over, a current of strong intensity and of opposite direction to the preceding one is sent through the coil in order to bring the carriage 8 against the first stop 91 and thus to open the contactor. As the elasticity of the flexible blades 58, 68 tends to push the carriage in its open position, the intensity of the current is reduced as soon as the second induction sensor 94 no longer detects the presence of the head of the second screw 96 in order to avoid the opening movement being too fast. The complete opening of the contactor is notified by the first induction sensor 93 detecting the presence of the head of the first screw 95. The current's intensity is then increased again during approximately 10 milliseconds in order to press the carriage 8 hard against the stop 91 to dampen the vibrations of the carriage 8. After this interval, a current of less intensity and of same direction than the preceding one is maintained through the coil, in order to generate a force sufficient for holding the carriage 8 against the first stop 91 until the tested component is evacuated and a new component is presented in front of the contactor. The control cycle is then repeated.

The control cycle of the actuating system described above is given by way of illustrative but by no means limitative example. The one skilled in the art will understand that it is possible to achieve the same result by using currents of different intensity, duration or directions.

A voice coil motor such as that described here above has the major advantage that the mass of the mobile part comprising the coil 4 and the carriage 8 can be kept very low, thus limiting the motor's inertia and ensuring a maximal acceleration of the carriage 8.

The wear and tear of such a movement generator is also minimal, since the only friction is that of the runners 81, 82 on the rails 9.

The movement of the voice coil motor, is however difficult to control. It is in particular difficult to limit the speed and amplitude of the carriage's movement accurately and thus to stop it without rebound against the stops 91, 92. Use of such a movement generator for actuating a contactor of electronic components is rendered possible only by associating it to an adapted control system, ensuring a progressive reduction of the speed of the contactor's flexible blades 58, 68 when approaching the component to be tested and especially limiting the maximal pressing force of the blades 58, 68 in order not to damage the component to be tested and to obtain an electric contact of sufficient quality for performing the test in good conditions.

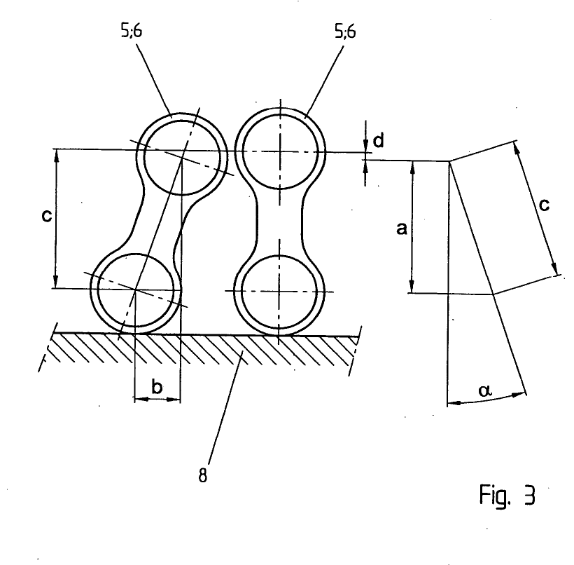

With reference to FIG. 3, in the preferred embodiment of the invention, the control system comprises the two connecting rods 5, 6 fastened by their lower axle to the carriage 8. The upper axle of the first connecting rod 5 is directly fastened to the lower part of the first axle 55 guided in a vertical guide through the system's frame 1. The second axle 62 of the second connecting rod 6 is connected to a reversing lever 7, constituted of a rigid metallic part placed more or less horizontally and capable of turning around an axis in its middle. The other extremity of the reversing lever 7 is connected to the lower extremity of the second axle 65, also guided in a vertical guide through the system's frame 1.

When the carriage 8 is in its first discrete position, against the stop 91, the connecting rods 5, 6 form an angle α relative to the vertical plane and their second axle is in its lower position on the vertical axis. The jaw 56 is pulled downwards by the axle 55 and the jaw 66 is pushed upwards by the axle 65 connected to the second connecting rod 6 through the reversing lever 7. The contactor is open, the components can be moved from one processing station to the next. In the preferred embodiment of the invention illustrated here by means of example, these connecting rods have the same length and form the same angle α with the vertical plane, when the contactor is open. It would also be conceivable to control the movements of the linear electromechanical transducer according to the invention and to actuate a contactor by means of connecting rod of different length and positions.

When the carriage 8 is in its second discrete position, against the second stop 92, the connecting rods 5, 6 are in more or less vertical position. Their second axle is thus in its highest position on the vertical axis. The jaw 56 is pushed upwards by the axle 55 and the jaw 66 is pulled downwards by the axle 65 through the reversing lever 7. The contactor is closed, the component's testing can be performed.

The functioning of the connecting rods 5, 6 is illustrated by the drawing of FIG. 3. When the contactor is open, the connecting rod 5, 6 forms an angle α with the vertical plane. The lower axle of the connecting rod 5, 6 connected to the carriage moves horizontally. The upper axle of the connecting rod 5, 6 connected to an axle or to the reversing lever 7 is guided in a vertical movement. When the carriage 8 moves towards its second discrete position to close the contactor, the connecting rods 5, 6 are brought in vertical position. The carriage's horizontal displacement b induces a vertical displacement d of the upper axle of the connecting rod 5, 6. The displacements d and b are connected by the formula:

$$d = b \cdot ( \frac{1 - cos α}{sin α} )$$

Thus, if the angle α remains small, the vertical displacement of the connecting rod's upper axle will remain considerably smaller than the horizontal displacement of its lower axle. The derivation of the aforementioned formula also shows that the vertical displacement speed diminishes considerably when approaching the vertical position of the connecting rod 5, 6.

This relation between the vertical displacement and the horizontal displacement offers several advantages.

A first advantage is the reduction of the speed of the contactor's flexible blades 58, 68 when approaching the contact point with the component to be tested. In the case of a rapid horizontal displacement of the carriage around the vertical position of the connecting rod 5, 6, the vertical speed of the upper axle of the connecting rod 5, 6 and consequently the speed of the contactor's blades 58, 68 is greatly reduced.

A second advantage is that the oscillations of the carriage 8 around its second discrete position have little influence on the position of the flexible blades 58, 68.

A third advantage is that the force of the linear electromechanical transducer is multiplied. Therefore, holding the contactor in closed position on the component to be tested requires only minimal force on the transducer's part.

An additional advantage is that since the vertical position of the upper axle of the connecting rod 5, 6 reaches an absolute maximum, the minimal distance between the contactor's jaws 56, 66 and consequently the squeezing or pressing force of the contactor on a particular type of component also reaches an absolute maximum that can be determined accurately. A movement of the carriage beyond its ideal second discrete position causes a slight reopening of the contactor, thus preventing the component to be tested to become damaged or the flexible blades 58, 68 to be excessively constrained. The precise moment of closing of the contactor on the component to be tested is however determined by means of the second induction sensor 94 and the precise moment of its detection can be adjusted by acting on the second screw 96.

In a variant embodiment of the actuating system according to the invention, the reversing lever 7 is eliminated and the upper axle of the second connecting rod 6 is directly fastened to the lower extremity of the second axle 65. The function of the reversing lever is fulfilled, for example, by the vertical positioning of the second connecting rod 6 when the carriage 8 is pressing against the first stop 91. In this manner, the carriage's displacement towards its second discrete position causes the second axle of the first connecting rod 5 to move upwards and the second axle of the second connecting rod 6 to move downwards so that it finds itself in a position forming an angle α relative to the vertical plane, which moves the jaws 56 and 66 closer together.

The preferred embodiment of the invention as described here above, specifies, by way of example, an actuating system for a contactor of electronic components, whose movement is generated by a horizontal linear voice coil motor and which serves to actuate, through a control system, a contactor moving on the vertical axis.

The principle of the invention could however also apply to any linear electromechanical movement generator having several discrete positions along any axis and whose movement, controlled by an appropriate mechanical system, serves to actuate a contactor along any other axis linearly independent from the first.

In a variant embodiment of the invention, the electromechanical transducer has a finite number of discrete positions, greater than two, thus impressing on the actuating system a corresponding number of discrete positions, for example to contact components whose disposition of contact points is more complex.

The contactor actuated by such a system can be of different type from that illustrated here above by means of example. It can for example comprise one or several pairs of jaws actuating flexible blades, one or several pairs of jaws of which only the upper or lower jaw is mobile, one or several series of flexible metallic blades coming into contact with the component to be tested by simple pressing on its contact points, or any combination of these systems. It can also be a contactor for grid array components, for example of the type “pin grid array” (PGA) or “ball grid array” (BGA), with the contactor then comprising for example a plate of metallic contacts arranged opposite the components' contacts and applied against its lower surface.

These different types of contacts require an adaptation of the actuating system according to the invention such that the latter can for example comprise only a single connecting rod for activating a single series of contacts, or on the contrary a greater number of connecting rods having for example different lengths and angles relative to the vertical plane, in order to impress on the different elements of the contactor movements having different speeds and amplitudes.

In a variant of the actuating system according to the invention, these connecting rods can advantageously be replaced by a group of cams.

1. A system for actuating a contactor of semi-conductor components comprising
a linear movement generator,
a contact force control system,
said movement generator being a linear electromechanical transducer having at least two discrete positions.

2. The actuating system of claim 1, said linear electromechanical transducer being a voice coil motor.

3. The actuating system of claim 2, said voice coil motor comprising a mobile electric coil placed between two fixed blocks of permanent magnets.

4. The actuating system of claim 3, said mobile electric coil being guided along an axis more or less parallel to the median-plane of the shortest segment between said two blocs of permanent magnets.

5. The actuating system of claim 3, said mobile electric coil being mounted on at least one runner guided on at least one linear rail.

6. The actuating system of claim 3, the amplitude of movement of said mobile electric coil being limited on each side by stops.

7. The actuating system of claim 1, said mechanism for limiting the contact force comprising at least one connecting rod.

8. The actuating system of claim 7, a first extremity of said at least one connecting rod being united with the mobile part of said movement generator.

9. The actuating system of claim 7, the second extremity of said at least one connecting rod being united with the first jaw of a contactor of semi-conductor components.

10. The actuating system of claim 7, the displacement axis of the second extremity of said at least one connecting rod being guided along an axis linearly independent from the displacement axis of the first extremity of said at least one connecting rod.

11. The actuating system of claim 7, comprising two connecting rods.

12. The actuating system of claim 11, each of said two connecting rods actuating a jaw of a contactor of semi-conductor components.

13. The actuating system of claims 11, comprising a reversing lever fastened to the second extremity of the second connecting rod.

14. Control cycle of a contactor actuating system according to one of the claims 1 to 13, comprising:
generating an electric current causing the contactor to close,
generating an electric current of lower intensity holding the contactor in closed position,
generating a current of opposite direction to the direction of the current previously generated causing the contactor to open,
generating an electric current of lower intensity holding the contactor in open position.
